(19) United States
(12) Patent Application Publication
(10) Pub. No.: US 2025/0351330 A1
(43) Pub. Date: Nov. 13, 2025

(54) SEMICONDUCTOR MEMORY DEVICES

(71) Applicant: Samsung Electronics Co., Ltd., Suwon-si (KR)

(72) Inventors: Yujin KIM, Suwon-si (KR); Jinwoo HAN, Suwon-si (KR); Bowon YOO, Suwon-si (KR)

(73) Assignee: Samsung Electronics Co., Ltd., Suwon-si (KR)

(21) Appl. No.: 19/019,689

(22) Filed: Jan. 14, 2025

(30) Foreign Application Priority Data
May 7, 2024 (KR) 10-2024-0059884

(51) Int. Cl. H10B 12/00; G11C 11/408

(52) U.S. Cl. CPC H10B 12/30; G11C 11/4085; H10B 12/50

(57) ABSTRACT

Provided is a semiconductor memory device including a substrate including a stack region, the stack region including a first step region and a second step region being at both ends of the stack region in a first horizontal direction, a plurality of word lines each extending in the first horizontal direction in the stack region, a plurality of bit lines extending in the vertical direction and spaced apart from each other in the first horizontal direction in the stack region, a plurality of memory cells between the plurality of word lines and the plurality of bit lines, a first word line contact and a second word line contact connected to each of the plurality of word lines, and a first sub-word line driver and a second sub-word line driver connected to the first word line contact and the second word line contact, respectively.

### CROSS-REFERENCE TO RELATED APPLICATION

This application is based on and claims priority under 35 U.S.C. § 119 to Korean Patent Application No. 10-2024-0059884, filed on May 7, 2024, in the Korean Intellectual Property Office, the disclosure of which is incorporated by reference herein in its entirety.

### BACKGROUND

The inventive concepts relate to semiconductor memory devices, and more specifically, to three-dimensional semiconductor memory devices including a plurality of memory cells arranged in three dimensions.

Higher-capacity semiconductor memory devices are required as electronic products are required to be miniaturized and multifunctional, and have higher performance, and increased integration is required to provide higher-capacity semiconductor memory devices. Because the degree of integration of a conventional semiconductor memory device including a plurality of memory cells arranged in two dimensions is mainly determined by the area occupied by a unit memory cell, the degree of integration of two-dimensional semiconductor memory devices is increasing but is still limited. Accordingly, a three-dimensional semiconductor memory device that increases memory capacity by stacking memory cells in a vertical direction on a substrate has been proposed to include multiple memory cells arranged in three dimensions.

### SUMMARY

The inventive concepts provide three-dimensional semiconductor memory devices with an increased degree of integration.

According to an example embodiment of the inventive concepts, a semiconductor memory device including a substrate includes a stack region, the stack region including a first step region and a second step region, the first step region and the second step region being at both ends of the stack region, respectively, in a first horizontal direction, a plurality of word lines each extending in the first horizontal direction in the stack region toward each of the first step region and the second step region, the plurality of word lines being spaced apart from each other in a vertical direction, a plurality of bit lines extending in the vertical direction in the stack region, the plurality of bit lines spaced apart from each other in the first horizontal direction, a plurality of memory cells between the plurality of word lines and the plurality of bit lines in the stack region, a first word line contact connected to each of the plurality of word lines in the first step region and a second word line contact connected to each of the plurality of word lines in the second step region, and a first sub-word line driver and a second sub-word line driver connected to the first word line contact and the second word line contact, respectively.

According to an example embodiment of the inventive concepts, a semiconductor memory device includes a lower structure, and an upper structure stacked on the lower structure, the upper structure including a first sub-word line driver and a second sub-word line driver, wherein the lower structure includes a substrate including a stack region, the stack region including a first step region and a second step region, the first step region and the second step region being at both ends of the stack region, respectively, in a first horizontal direction, a plurality of word lines each extending in the first horizontal direction in the stack region toward each of the first step region and the second step region, the plurality of word lines being spaced apart from each other in a vertical direction, a plurality of bit lines extending in the vertical direction in the stack region, the plurality of bit lines spaced apart from each other in the first horizontal direction, a plurality of memory cells between the plurality of word lines and the plurality of bit lines in the stack region, and a first word line contact connected to each of the plurality of word lines in the first step region and a second word line contact connected to each of the plurality of word lines in the second step region, wherein each of the plurality of word lines is electrically connected to the first sub-word line driver through the first word line contact, and is electrically connected to the second sub-word line driver through the second word line contact.

According to an example embodiment of the inventive concepts, a semiconductor memory device includes a lower structure, and an upper structure stacked on the lower structure, the upper structure including a first sub-word line driver and a second sub-word line driver, wherein the lower structure includes a substrate including a stack region, the stack region including a first step region and a second step region, the first step region and the second step region being at both ends of the stack region, respectively, in a first horizontal direction, a plurality of word lines each extending in the first horizontal direction in the stack region toward each of the first step region and the second step region, the plurality of word lines being spaced apart from each other in a vertical direction, a plurality of bit lines extending in the vertical direction in the stack region, the plurality of bit lines spaced apart from each other in the first horizontal direction, a plurality of memory cells between the plurality of word lines and the plurality of bit lines in the stack region, and a first word line contact connected to each of the plurality of word lines in the first step region and a second word line contact connected to each of the plurality of word lines in the second step region, each of the plurality of word lines is electrically connected to the first sub-word line driver through the first word line contact, and is electrically connected to the second sub-word line driver through the second word line contact, each of the plurality of memory cells includes a cell transistor and an information storage element, the cell transistor includes a semiconductor pattern including a source region connected to a corresponding one of the plurality of bit lines, a channel region surrounded by a corresponding one of the plurality of word lines, and a drain region connected to the information storage element, and the source region, the channel region, and the drain region are sequentially arranged from the corresponding one of the plurality of bit lines in a second horizontal direction different from the first horizontal direction.

### BRIEF DESCRIPTION OF THE DRAWINGS

Some example embodiments will be more clearly understood from the following detailed description taken in conjunction with the accompanying drawings in which:

FIG. 1 is an equivalent circuit diagram illustrating a stack cell array of a semiconductor memory device according to an example embodiment;

FIG. 2 is a block diagram illustrating a semiconductor memory device according to an example embodiment;

FIG. 3 is a perspective view illustrating a semiconductor memory device according to an example embodiment;

FIGS. 4A, 4B, and 4C are a perspective view and cross-sectional views of a part of a semiconductor memory device according to an example embodiment;

FIG. 5 is a planar layout view illustrating a semiconductor memory device according to an example embodiment;

FIG. 6 is a planar layout view illustrating a semiconductor memory device according to an example embodiment;

FIG. 7 is an equivalent circuit diagram illustrating a stack cell array of a semiconductor memory device according to an example embodiment;

FIG. 8 is a planar layout view illustrating a semiconductor memory device according to an example embodiment;

FIG. 9 is a block diagram illustrating a row decoder included in a semiconductor memory device according to an example embodiment; and

FIG. 10 is a circuit diagram illustrating a sub-word line driver circuit of FIG. 9.

### DETAILED DESCRIPTION

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

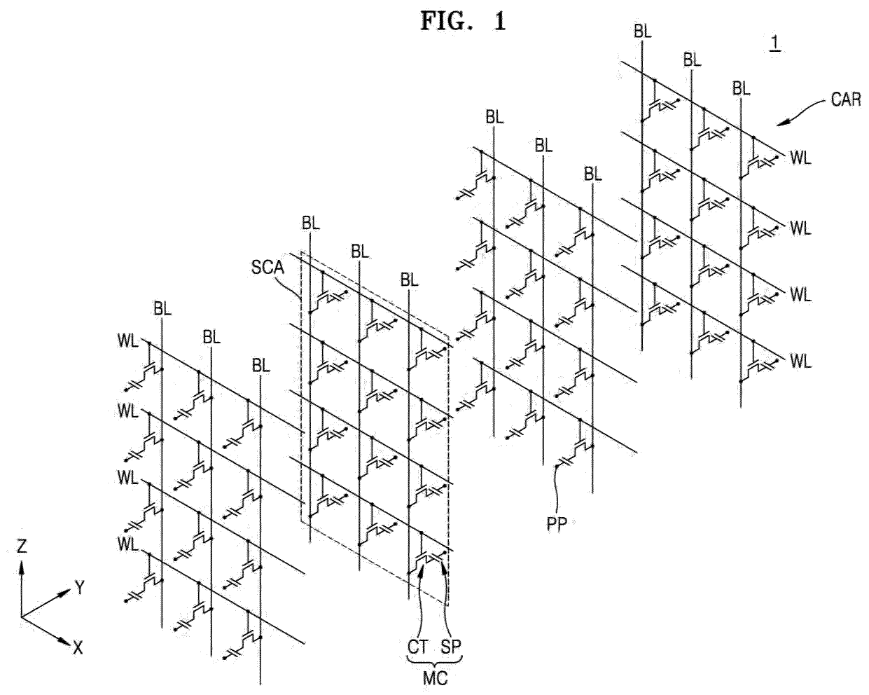

FIG. 1 is an equivalent circuit diagram illustrating a stack cell array of a semiconductor memory device according to an example embodiment.

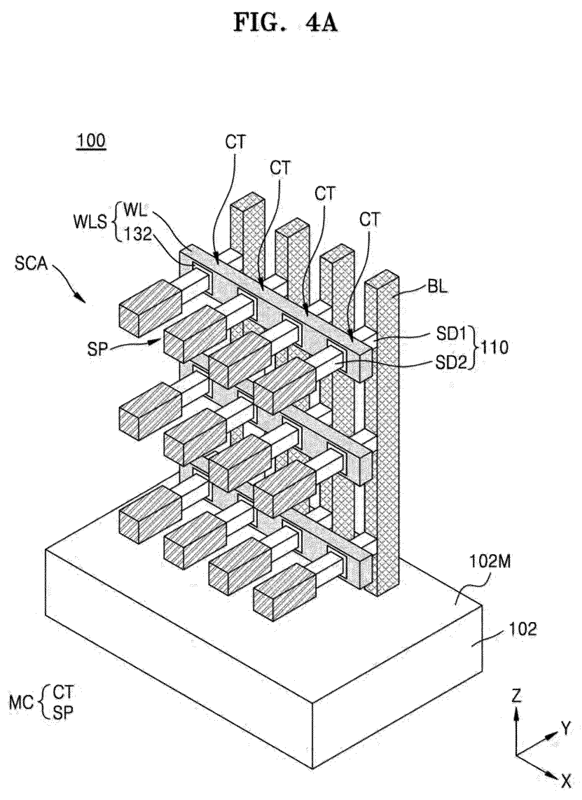

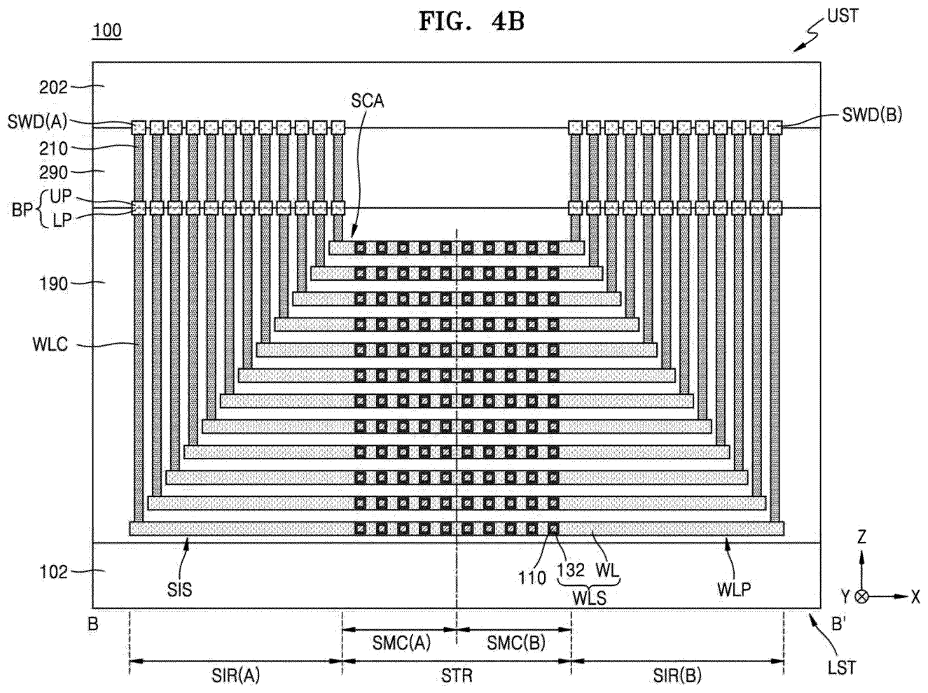

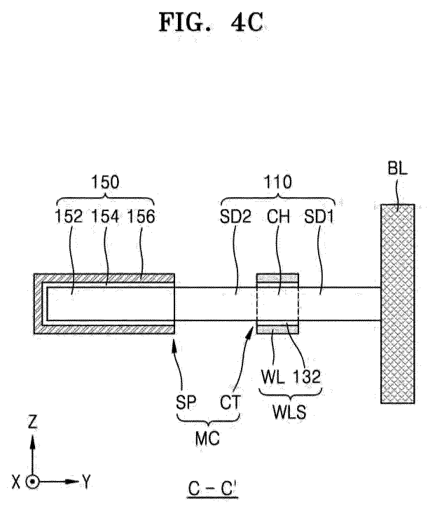

Referring to FIG. 1, a stack cell array structure CAR of a semiconductor memory device 1 according to an example embodiment may include a plurality of sub-cell arrays SCA. Each of the sub-cell arrays SCA may include a plurality of bit lines BL, a plurality of word lines WL, and a plurality of memory cells MC. Each of the plurality of memory cells MC includes a cell transistor CT and an information storage element SP. One cell transistor CT may be arranged between one word line WL and one bit line BL. The information storage element SP may be connected to the cell transistor CT. The information storage element SP may be a memory element capable of storing data. The information storage element SP may include a memory element using a capacitor, a memory element using a magnetic tunnel junction pattern, or a memory element using a variable resistor including a phase change material. In some example embodiments, the memory cell MC may be a DRAM cell, and the information storage element SP may be a capacitor, and a specific example thereof will be described later with reference to FIG. 4C.

The word lines WL may be a conductive pattern (e.g., a metal line) spaced apart from a substrate and arranged above the substrate. The plurality of word lines WL may extend in the first horizontal direction (X direction). The word lines WL in one sub-cell array SCA may be spaced apart from each other in the vertical direction (Z direction). Each of the bit lines BL may be a conductive pattern (e.g., a metal line) extending from the substrate in a vertical direction (Z direction). The bit lines BL in one sub-cell array SCA may be spaced apart from each other in the first horizontal direction (X direction).

In the stack cell array structure CAR, the plurality of word lines WL extend in the first horizontal direction (X direction) and may be spaced apart from each other in the second horizontal direction (Y direction) and the vertical direction (Z direction), respectively. In the stack cell array structure CAR, the plurality of bit lines BL may extend in the vertical direction (Z direction) and may be spaced apart from each other in each of the first horizontal direction (X direction) and the second horizontal direction (Y direction). The plurality of sub-cell arrays SCA may be arranged in the second horizontal direction (Y direction). The second horizontal direction (Y direction) may be orthogonal to the first horizontal direction (X direction).

A gate of the cell transistor CT may be connected to the word line WL, and a source region of the cell transistor CT may be connected to the bit line BL. An information storage element SP may be connected to a drain region of the cell transistor CT. In some example embodiments, the information storage element SP may be a capacitor including a first electrode, a second electrode, and a capacitor dielectric layer between the first electrode and the second electrode, and the first electrode of the capacitor may be connected to the drain region of the cell transistor CT, and the second electrode of the capacitor may be connected to a ground wire PP.

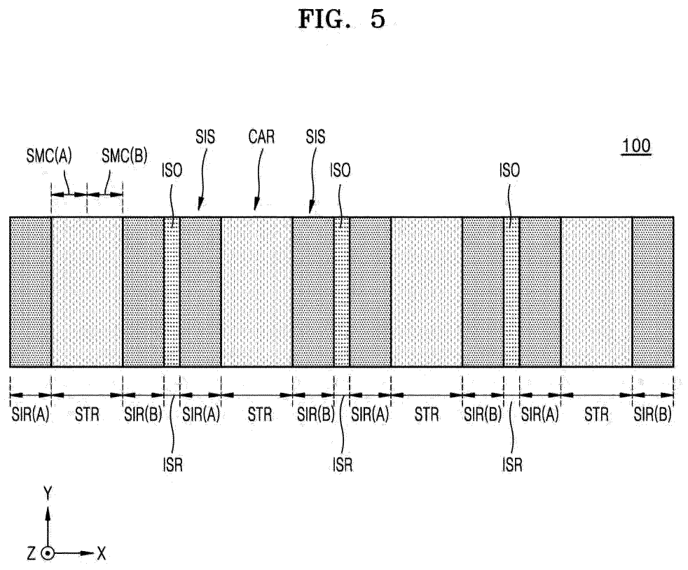

The stack cell array structure CAR of the semiconductor memory device 1 includes a plurality of memory cells MC spaced apart from each other in each of the first horizontal direction (X direction) and the vertical direction (Z direction), respectively, and are arranged to form rows and columns, a plurality of bit lines BL connected to the cell transistors CT of the memory cells MC arranged in the vertical direction (Z direction), extending in the vertical direction (Z direction), and spaced apart from each other in the first horizontal direction (X direction), and a plurality of sub-cell arrays SCA each including a plurality of word lines WL extending in the first horizontal direction (X direction) and spaced apart from each other in the vertical direction (Z direction), and the plurality of sub-cell arrays SCA may be arranged in the second horizontal direction (Y direction). The semiconductor memory device 1 may include a plurality of stack cell array structures CAR, which will be described with reference to FIG. 5.

The first horizontal direction (X direction), the second horizontal direction (Y direction), and the vertical direction (Z direction) may be referred to as a first direction, a second direction, and a third direction, respectively. Alternatively, the first horizontal direction (X direction), the vertical direction (Z direction), and the second horizontal direction (Y direction) may be referred to as a first direction, a second direction, and a third direction, respectively. The first direction, the second direction, and the third direction may be orthogonal to each other.

In some example embodiments, the source region and the drain region of the cell transistor CT and the information storage element SP may be arranged in the second horizontal direction (Y direction) from the bit line BL connected to the source region of the cell transistor CT. Two groups each including a source region and a drain region of the cell transistor CT, and an information storage element SP and connected to a corresponding one of the two bit lines BL adjacent to each other in the second horizontal direction (Y direction) may be arranged in opposite directions. For example, the source and drain regions of the cell transistor CT, and the information storage element SP, which are connected to one of the two bit lines BL adjacent to each other in the second horizontal direction (Y direction) may be sequentially arranged in the second horizontal direction (Y direction), and the source region and the drain region of the cell transistor CT, and the information storage element SP, which are connected to the other one of the two bit lines BL adjacent to each other may be arranged in a direction opposite to the second horizontal direction (Y direction). For example, the plurality of bit lines BL may include a first bit line, a second bit line, a third bit line, and a fourth bit line arranged sequentially adjacent to each other in the second horizontal direction (Y direction). Memory cells MC may not be arranged between the first bit line and the second bit line. Two memory cells MC may be arranged between the second bit line and the third bit line in the second horizontal direction (Y direction) at the same vertical level. Memory cells MC may not be arranged between the third bit line and the fourth bit line.

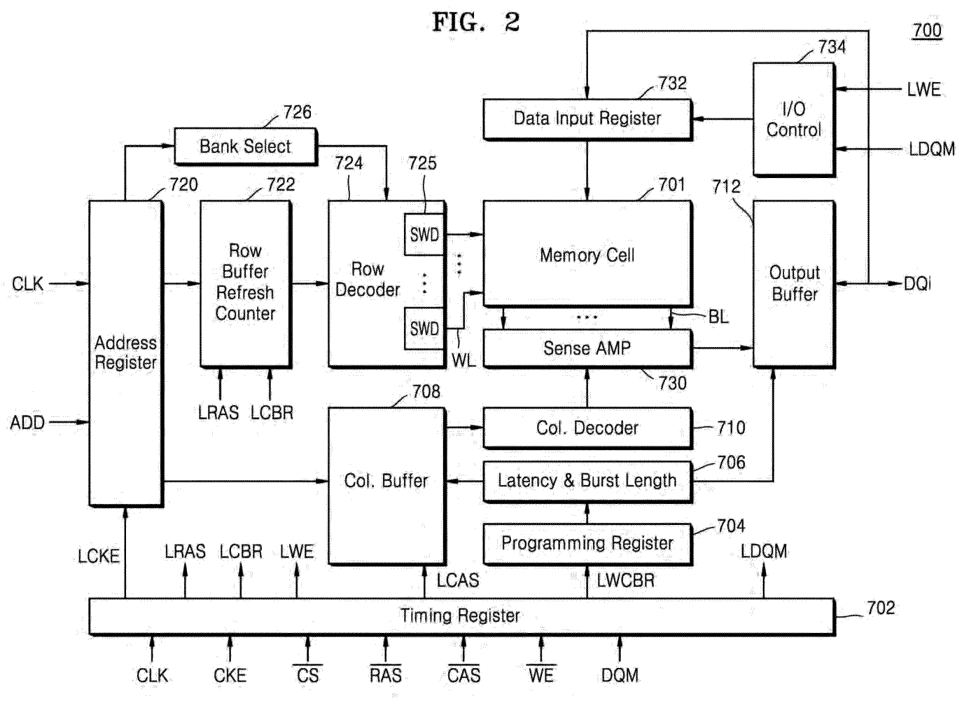

FIG. 2 is a block diagram illustrating a semiconductor memory device according to an example embodiment.

Referring to FIG. 2, a semiconductor memory device 700 may include a memory cell array 701 including DRAM cells, which are memory cells, and various circuit blocks for driving the DRAM cells. For example, a timing register 702 may be activated when a chip selection signal CSB changes from an inactivation level (e.g., logic high) to an activation level (e.g., logic low). The timing register 702 may receive a command signal such as a clock signal CLK, a clock enable signal CKE, a chip selection signal CSB, a row address strobe signal RASB, a column address strobe signal CASB, a write enable signal WEB, and a data input/output mask signal DQM, from the outside, and process the received command signal to generate various internal command signals LRAS, LCBR, LWE, LCAS, LWCBR, and LDQM for controlling the circuit blocks.

Some internal command signals generated from the timing register 702 are stored in a programming register 704. For example, latency information, burst length information, or the like related to data output may be stored in the programming register 704. The internal command signals stored in the programming register 704 may be provided to a latency/burst length control unit 706, and the latency/burst length control unit 706 may provide a control signal for controlling the latency or burst length of a data output to the column decoder 710 through the column address buffer 708, or to an output buffer 712.

An address register 720 may receive a clock signal CLK and an address signal ADD from the outside. A row address signal may be provided to a row decoder 724 through a row buffer refresh counter 722. Furthermore, a column address signal may be provided to a column decoder 710 through a column buffer 708. The row buffer refresh counter 722 may further receive a refresh address signal generated from a refresh counter in response to refresh commands LRAS and LCBR, and may provide either a row address signal or a refresh address signal to the row decoder 724. In addition, the address register 720 may provide a bank signal for selecting a bank to a bank selection unit 726.

The row decoder 724 may decode a row address signal or a refresh address signal input from the row buffer refresh counter 722. The row decoder 724 may include a plurality of sub-word line drivers 725. The sub-word line drivers 725 may activate the word lines WL of a memory cell array 701. The sub-word line drivers 725 may be arranged adjacent to the memory cell array 701 to form blocks at desired (or alternatively, predetermined) intervals within the row decoder 724. For example, the sub-word line drivers 725 may be arranged adjacent to one end of the memory cell array 701 perpendicular to a sense amplifier 730.

The column decoder 710 may decode a column address signal and perform a selection operation on a bit line of the memory cell array 701. For example, a column selection line may be applied to the semiconductor memory device 700 to perform a selection operation through the column selection line.

The sense amplifier 730 may amplify the data of a memory cell selected by the row decoder 724 and the column decoder 710 and provide the amplified data to an output buffer 712. Data for recording a data cell is provided to the memory cell array 701 through a data input register 732, and an input/output controller 734 may control a data transfer operation through the data input register 732.

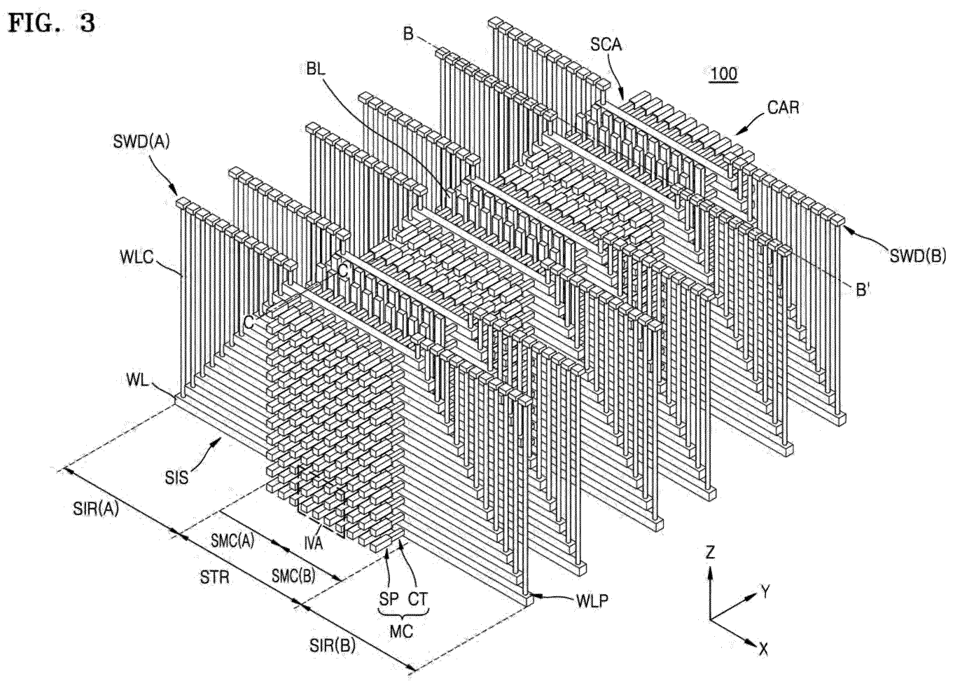

FIG. 3 is a perspective view illustrating a semiconductor memory device according to an example embodiment.

Referring to FIG. 3, a semiconductor memory device 100 includes a stack region STR and step regions SIR. A stack cell array structure CAR may be positioned in the stack region STR, and step structures SIS may be positioned in the step regions SIR. The step regions SIR may be arranged on both sides of the stack region STR in the first horizontal direction (X direction). For example, a pair of step regions SIR may be arranged on both sides of the stack region STR in the first horizontal direction (X direction). The step region SIR arranged on one side of the stack region STR in the first horizontal direction (X direction) may be referred to as a first step region SIR(A), and the step region SIR arranged on the other side of the stack region STR in the first horizontal direction (X direction) may be referred to as a second step region SIR(B). A step structure SIS may be positioned in each of the first step region SIR(A) and the second step region SIR(B).

The stack cell array structure CAR may include a plurality of sub-cell arrays SCA. The plurality of sub-cell arrays SCA included in one stack cell array structure CAR may be arranged in the second horizontal direction (Y direction). Each of the sub-cell arrays SCA may include a plurality of bit lines BL, a plurality of word lines WL, and a plurality of memory cells MC. Each of the plurality of memory cells MC includes a cell transistor CT and an information storage element SP.

The plurality of word lines WL may extend in the first horizontal direction (X direction). In the stack cell array structure CAR, the plurality of word lines WL extend in the first horizontal direction (X direction) and may be spaced apart from each other in the second horizontal direction (Y direction) and the vertical direction (Z direction), respectively. The word lines WL in one sub-cell array SCA may be spaced apart from each other in the vertical direction (Z direction).

Bit lines BL may extend from a substrate 102 (FIG. 4A) in a vertical direction (Z direction). In the stack cell array structure CAR, the plurality of bit lines BL may extend in the vertical direction (Z direction) and may be spaced apart from each other in each of the first horizontal direction (X direction) and the second horizontal direction (Y direction). The bit lines BL in one sub-cell array SCA may be spaced apart from each other in the first horizontal direction (X direction).

One cell transistor CT may be arranged between one word line WL and one bit line BL. The information storage element SP may be connected to the cell transistor CT. The information storage element SP may be a memory element capable of storing data. A gate of the cell transistor CT may be connected to the word line WL, and a source region of the cell transistor CT may be connected to the bit line BL. An information storage element SP may be connected to a drain region of the cell transistor CT.

In some example embodiments, the source region and the drain region of the cell transistor CT and the information storage element SP may be arranged in the second horizontal direction (Y direction) from the bit line BL connected to the source region of the cell transistor CT. Two groups each including a source region and a drain region of the cell transistor CT, and an information storage element SP and are connected to a corresponding one of the two bit lines BL adjacent to each other in the second horizontal direction (Y direction) may be arranged in opposite directions. For example, the source and drain regions of the cell transistor CT, and the information storage element SP, which are connected to one of the two bit lines BL adjacent to each other in the second horizontal direction (Y direction) may be sequentially arranged in the second horizontal direction (Y direction), and the source region and the drain region of the cell transistor CT, and the information storage element SP, which are connected to the other of the two bit lines BL adjacent to each other may be arranged in a direction opposite to the second horizontal direction (Y direction). For example, the plurality of bit lines BL may include a first bit line, a second bit line, a third bit line, and a fourth bit line arranged sequentially adjacent to each other in the second horizontal direction (Y direction). Memory cells MC may not be arranged between the first bit line and the second bit line. Two memory cells MC may be arranged between the second bit line and the third bit line in the second horizontal direction (Y direction) at the same vertical level. Memory cells MC may not be arranged between the third bit line and the fourth bit line.

Each of the plurality of word lines WLs may extend from the stack region STR in the first horizontal direction (X direction) to a pair of step regions SIR arranged on both sides of the stack region STR in the first horizontal direction (X direction). For example, each of the plurality of word lines WL may extend from the first step region SIR(A) to the second step region SIR(B) via the stack region STR. The plurality of word lines WL may have a step structure. An extension length of the plurality of word lines WL in the first horizontal direction (X direction) may decrease from the lower side to the upper side in the vertical direction (Z direction). For example, an extension length in the first horizontal direction (X direction) of the word line WL located below from among the plurality of word lines WL spaced apart from each other in the vertical direction (Z direction) may be greater than an extension length of the word line WL located above in the first horizontal direction (X direction). For example, an extension length of the lowermost word line WL from among word lines WL stacked in the vertical direction (Z direction) in one sub-cell array SCA may be greater than an extension length of each of the remaining word lines WL. An extension length of the uppermost word line WL from among word lines WL stacked in the vertical direction (Z direction) in one sub-cell array SCA may be less than an extension length of each of the remaining word lines WL. Word line pads WLP may be positioned at both ends of each of the plurality of word lines WL. A part of the other word line WL may not be positioned above the word line pad WLP in the vertical direction (Z direction) in one sub-cell array SCA.

One word line WL may include a pair of word line pads WLP at both ends in the first horizontal direction (X direction). A word line contact WLC may be connected to the word line pad WLP. The word line pad WLP may be connected to a sub-word line driver SWD through the word line contact WLC. A lower end of the word line contact WLC may be in contact with the word line pad WLP. Although the top end of the word line contact WLC is shown to be in contact with the sub-word line driver SWD in FIG. 3, example embodiments are not limited thereto. For example, a wiring and/or contact may be arranged between the top end of the word line contact WLC and the sub-word line driver SWD to electrically connect the word line contact WLC and the sub-word line driver SWD.

The step structure SIS may include parts of the plurality of word lines WL extending from the stack region STR to the step regions SIR and each word line including the word line pad WLP. The step structure SIS located in the first step region SIR(A) may be referred to as a first step structure, and the step structure SIS located in the second step region SIR(B) may be referred to as a second step structure. The word line pad WLP positioned in the first step region SIR(A) may be referred to as a first word line pad, and the word line pad WLP positioned in the second step region SIR(B) may be referred to as a second word line pad.

The plurality of sub-word line drivers SWD may include word line pads WLP located in the first step region SIR(A). That is, first sub-word line drivers SWD(A) may be electrically connected to the first word line pads. Word line pads WLP located in the second step region SIR(B) (e.g., second sub-word line drivers SWD(B)) may be electrically connected to the second word line pads.

The plurality of memory cells MC included in the stack cell array structure CAR positioned in the stack region STR may include a first sub-memory cell group SMC(A) adjacent to the first step region SIR(A) and a second sub-memory cell group SMC(B) adjacent to the second step region SIR(B). Each of the memory cells MC included in the first sub-memory cell group SMC(A) may be electrically connected to the first sub-word line driver SWD(A) through the word line WL. Each of the memory cells MC included in the second sub-memory cell group SMC(B) may be electrically connected to the second sub-word line driver SWD(B) through the word line WL. That is, the first sub-word line driver SWD(A) may activate the word line WL connected to the memory cell MC included in the first sub-memory cell group SMC(A) to select the memory cell MC included in the first sub-memory cell group SMC(A) together with the bit line BL, and the second sub-word line driver SWD(B) may activate the word line WL connected to the memory cell MC included in the second sub-memory cell group SMC(B) to select the memory cell MC included in the second sub-memory cell group SMC(B) together with the bit line BL.

The semiconductor memory device 100 according to the inventive concepts includes a pair of word line pads WLP at both ends of one word line WL in the first horizontal direction (X direction), and includes a pair of sub-word line drivers SWD (e.g., the first sub-word line driver SWD(A) and the second sub-word line driver SWD(B)) electrically connected to the pair of word line pads WLP so that the number of memory cells MC arranged in the first horizontal direction (X direction) in one stack region STR may be increased. Therefore, the degree of integration of the semiconductor memory device 100 may be increased.

FIGS. 4A, 4B, and 4C are a perspective view and cross-sectional views of a part of a semiconductor memory device according to an example embodiment. Specifically, FIG. 4A is an enlarged perspective view illustrating a part IVA of FIG. 3, FIG. 4B is a cross-sectional view taken along line B-B′ of FIG. 3, and FIG. 4C is a cross-sectional view taken along line C-C′ of FIG. 3.

Referring to FIGS. 4A to 4C together, a semiconductor memory device 100 includes a lower structure LST and an upper structure UST stacked on the lower structure LST. The lower structure LST and the upper structure UST may be referred to as a first structure and a second structure, or a cell structure and a peripheral circuit structure, respectively.

The lower structure LST has a stack region STR and step regions SIR. The step region SIR arranged on one side of the stack region STR in the first horizontal direction (X direction) may be referred to as a first step region SIR(A), and the step region SIR arranged on the other side of the stack region STR in the first horizontal direction (X direction) may be referred to as a second step region SIR(B). The lower structure LST includes a substrate 102 and a sub-cell array SCA arranged in the stack region STR and step structures SIS arranged in the step regions SIR, on the substrate 102. The step structure SIS located in the first step region SIR(A) may be referred to as a first step structure, and the step structure SIS located in the second step region SIR(B) may be referred to as a second step structure.

The sub-cell array SCA may include a substrate 102, a plurality of word lines WL spaced apart from a main surface 102M of the substrate 102 and arranged on the substrate 102, a plurality of bit lines BL extending in the vertical direction (Z direction) from the main surface 102M of the substrate 102, a plurality of cell transistors CT arranged between the plurality of word lines WL and the plurality of bit lines BL, and a plurality of information storage elements SP connected to the plurality of cell transistors CT, respectively. A cell transistor CT and an information storage element SP may constitute a memory cell MC.

The substrate 102 may include, for example, silicon (Si), such as crystalline Si, polycrystalline Si, or amorphous Si. In some example embodiments, the substrate 102 may include at least one compound semiconductor selected from a semiconductor element such as germanium (Ge), silicon germanium (SiGe), silicon carbide (SiC), gallium arsenide (GaAs), indium arsenide (InAs), and indium phosphide (InP). In some example embodiments, the substrate 102 may include a silicon-on-insulator (SOI) substrate or a germanium-on-insulator (GeOI) substrate. For example, the substrate 102 may include a buried oxide layer (BOX). The substrate 102 may include a conductive region, for example, an impurity-doped well, or an impurity-doped structure.

The plurality of word lines WL extend in the first horizontal direction (X direction) on the substrate 102 and may be spaced apart from each other in the vertical direction (Z direction). The plurality of bit lines BL extend from the substrate 102 in the vertical direction (Z direction), and may be spaced apart from each other in the first horizontal direction (X direction).

One cell transistor CT may be arranged between one word line WL and one bit line BL. The information storage element SP may be connected to the cell transistor CT. The cell transistor CT and the information storage element SP may be sequentially arranged in the second horizontal direction (Y direction) from the bit line BL to which the cell transistor CT is connected.

The word line WL may be adjacent to a semiconductor pattern 110. In some embodiments, the word line WL may surround the semiconductor pattern 110. A gate dielectric layer 132 may be arranged between the word line WL and the semiconductor pattern 110. The word line WL and the gate dielectric layer 132 may constitute a word line structure WLS. The semiconductor pattern 110 and the word line structure WLS may constitute a cell transistor CT.

The semiconductor pattern 110 may include a source region SD1, a drain region SD2, and a channel region CH arranged between the source region SD1 and the drain region SD2. The source area SD1 may be connected to the bit line BL, and the drain area SD2 may be connected to the information storage element SP. The source region SD1, the channel region CH, and the drain region SD2 may be sequentially arranged in the second horizontal direction (Y direction) from the bit line BL. In some example embodiments, the semiconductor pattern 110 may penetrate the word line WL. For example, the channel region CH may be a part of the semiconductor pattern 110 that penetrates the word line WL.

In some example embodiments, the semiconductor pattern 110 may include a material having the same or similar etching characteristics as or to that of the substrate 102, or may include the same material as the substrate 102. In some example embodiments, the semiconductor pattern 110 may include Si. In some example embodiments, the semiconductor pattern 110 may include a single crystal semiconductor material. For example, the semiconductor pattern 110 may include single crystal Si. In some other example embodiments, the semiconductor pattern 110 may include a two-dimensional (2D) semiconductor material or an oxide semiconductor material. For example, the 2D semiconductor material may include MoS₂, WSe₂, graphene, carbon nanotubes, or a combination thereof. For example, the oxide semiconductor material may include InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, or a combination thereof. For example, the semiconductor pattern 110 may include a single layer or multiple layers of the oxide semiconductor material. In some example embodiments, the semiconductor pattern 110 may include a material having a band gap energy greater than that of silicon. For example, the semiconductor pattern 110 may include a material having a bandgap energy of about 1.5 eV to about 5.6 eV. For example, each semiconductor pattern 110 may include a material capable of having optimal or desired channel performance when having a bandgap energy of about 2.0 eV to about 4.0 eV.

First impurities having a first conductivity type may be injected into the source region SD1 and the drain region SD2 of the semiconductor pattern 110, and second impurities having a second conductivity type different from the first conductivity type may be injected into the channel region CH. In some example embodiments, the first conductivity type may be an n-type, and the second conductivity type may be a p-type.

In some example embodiments, the word line WL may include a conductive barrier layer covering the gate dielectric layer 182 and a conductive filling layer covering the conductive barrier layer. The conductive barrier layer may include, for example, metal, conductive metal nitride, conductive metal silicide, or a combination thereof. For example, the conductive barrier layer may include TiN. The conductive filling layer may include doped silicon, Ru, RuO, Pt, PtO, Ir, IrO, SRO(SrRuO), BSRO((Ba, Sr)RuO), CRO(CaRuO), BaRuO, La(Sr, Co)O, Ti, TiN, W, WN, Ta, TaN, TiAlN, TiSiN, TaAlN, TaSiN, or a combination thereof. In some example embodiments, the conductive filling layer may include W.

The gate dielectric layer 132 may include at least one selected from a silicon oxide, a high-k dielectric material having a dielectric constant higher than that of a silicon oxide and a ferroelectric material. In some example embodiments, the gate dielectric layer 132 may have a stacked structure of a first dielectric layer made of silicon oxide and a second dielectric layer made of at least one selected from a high-k dielectric material and a ferroelectric material. For example, the high-k dielectric material and the ferroelectric material include at least one material selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), tantalum strontium bismuth (STB), bismuth iron oxide (BFO), strontium titanium oxide (SrTiO), yttrium oxide (YO), aluminum oxide (AlO), and lead scandium tantalum oxide (PbScTaO).

The bit line BL may consist of a conductive barrier layer in contact with one end of the semiconductor pattern 110, for example, the source region SD1, and a conductive filling layer covering the conductive barrier layer. The conductive barrier layer may include, for example, metal, conductive metal nitride, conductive metal silicide, or a combination thereof. For example, the conductive barrier layer may include TiN. The conductive filling layer may include doped silicon, Ru, RuO, Pt, PtO, Ir, IrO, SRO(SrRuO), BSRO((Ba, Sr)RuO), CRO(CaRuO), BaRuO, La(Sr, Co)O, Ti, TiN, W, WN, Ta, TaN, TiAlN, TiSiN, TaAlN, TaSiN, or a combination thereof. In some example embodiments, the conductive filling layer may include W.

In some example embodiments, the information storage element SP may be a capacitor 150 including a first electrode 152, a second electrode 156, and a capacitor dielectric layer 154 arranged between the first electrode 152 and the second electrode 156. The capacitor 150 may include the first electrode 152 connected to the drain region SD2 of the semiconductor pattern 110 and extending in the second horizontal direction (Y direction), the capacitor dielectric layer 154 covering the first electrode 152, and the second electrode 156 covering the capacitor dielectric layer 154. The second electrode 156 may be connected to the ground wire PP shown in FIG. 1 or may be a part of the ground wire PP. The first electrode 152 and the second electrode 156 may be referred to as a lower electrode and an upper electrode, respectively. The capacitor dielectric layer 154 may be arranged between the first electrode 152 and the second electrode 156.

The first electrode 152 may include metal, conductive metal nitride, conductive metal silicide, or a combination thereof. In some example embodiments, the first electrode 152 may include a high melting point metal layer, such as cobalt, titanium, nickel, tungsten, and molybdenum. For example, the first electrode 152 may include a metal nitride layer, such as a titanium nitride layer, a titanium silicon nitride layer, a titanium aluminum nitride layer, a tantalum nitride layer, a tantalum silicon nitride layer, a tantalum aluminum nitride layer, and a tungsten nitride layer.

The capacitor dielectric layer 154 may include at least one selected from a high-k dielectric material having a dielectric constant higher than that of a silicon oxide and a ferroelectric material. For example, the capacitor dielectric layer 154 may include at least one of a metal oxide or a dielectric material having a perovskite structure. For example, the capacitor dielectric layer 154 includes at least one material selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), tantalum strontium bismuth (STB), bismuth iron oxide (BFO), strontium titanium oxide (SrTiO), yttrium oxide (YO), aluminum oxide (AlO), and lead scandium tantalum oxide (PbScTaO).

The second electrode 156 may include doped silicon, Ru, RuO, Pt, PtO, Ir, IrO, SRO(SrRuO), BSRO(((Ba, Sr)RuO), CRO(CaRuO), BaRuO, La(Sr, Co)O, Ti, TiN, W, WN, Ta, TaN, TiAlN, TiSiN, TiAlN, TaSiN, or a combination thereof. In some example embodiments, the second electrode 156 may include W. Although FIGS. 3 to 4C illustrate that the plurality of information storage elements SP are spaced apart from each other, example embodiments are not limited thereto. In some example embodiments, when the plurality of information storage elements SP are a plurality of capacitors 150, the plurality of second electrodes 156 of the plurality of capacitors 150 included in the sub-cell array SCA are connected to each other to form an integral body. In some example embodiments, when the plurality of information storage elements SP are the plurality of capacitors 150, and when the plurality of capacitors 150 included in each of the pair of sub-cell arrays SCA adjacent in the second horizontal direction (Y direction) face and are adjacent to each other, the plurality of second electrodes 156 of the plurality of capacitors 150 included in each of the pair of sub-cell arrays SCA may be connected to each other to be integrated.

Each of the plurality of word lines WLs may extend from the stack region STR in the first horizontal direction (X direction) to a pair of step regions SIR arranged on both sides of the stack region STR in the first horizontal direction (X direction). For example, each of the plurality of word lines WL may extend from the first step region SIR(A) to the second step region SIR(B) via the stack region STR. The plurality of word lines WL may have a step structure. An extension length of the plurality of word lines WL in the first horizontal direction (X direction) may decrease from the lower side to the upper side in the vertical direction (Z direction). Word line pads WLP may be positioned at both ends of each of the plurality of word lines WL. A part of the other word line WL may not be positioned above the word line pad WLP in the vertical direction (Z direction) in one sub-cell array SCA.

The step structure SIS may include word line pads WLP, respectively, and may include parts of the plurality of word lines WL extending from the stack region STR to the step region SIR. The word line pad WLP positioned in the first step region SIR(A) may be referred to as a first word line pad, and the word line pad WLP positioned in the second step region SIR(B) may be referred to as a second word line pad. One word line WL may include a pair of word line pads WLP at both ends in the first horizontal direction (X direction). A word line contact WLC may be connected to the word line pad WLP.

When word line contacts WLC are connected to corresponding word lines WL included in one sub-cell array SCA in one step region SIR, respectively, the extension lengths of the word line contacts WLC arranged in one step region SIR in the vertical direction (Z direction) may be different from each other. Among the word line contacts WLC arranged in one step region SIR, an extension length of the word line contact WLC in the vertical direction (Z direction), which is located relatively far from the stack region STR adjacent in the first horizontal direction (X direction) may be greater than an extension length of the word line contact WLC in the vertical direction (Z direction), which is located relatively close to each other. The extension lengths of the word line contacts WLC in the vertical direction (Z direction) may increase away from the stack region STR in the first horizontal direction (X direction). The word line contact WLC may include metal, conductive metal nitride, conductive metal silicide, or a combination thereof. A first bonding pad part LP may be connected to a top end of the word line contact WLC.

A first insulating structure 190 may cover the sub-cell array SCA and the step structure SIS on the substrate 102. The first insulating structure 190 may surround the plurality of word lines WL, the plurality of word line contacts WLC, and the plurality of first bonding pad parts LP. The top surface of the first bonding pad part LP and the top surface of the first insulating structure 190 may be arranged on the same plane.

In some example embodiments, the first insulating structure 190 may include an insulating material that may include silicon oxide, silicon nitride, a low-k dielectric material, or a combination thereof. The low-k dielectric material is a material with a lower dielectric constant than silicon oxide, and may include, for example, phosphosilicate glass (PSG), borophosphosilicate glass (BPSG), fluorosilicate glass (FSG), organosilicate glass (OSG), spin-on-glass (SOG), spin-on-polymer, or a combination thereof. In some example embodiments, the first insulating structure 190 may include an ultra low-k (ULK) layer having an ultra low dielectric constant k of about 2.2 to about 2.4. The ULK layer may include SiOC or SiCOH. The first bonding pad part LP may include a conductive material which may include copper (Cu), gold (Au), silver (Ag), aluminum (Al), tungsten (W), titanium (Ti), tantalum (Ta), or a combination thereof.

The upper structure UST may include a peripheral circuit board 202, a second insulating structure 290 covering a lower part of the peripheral circuit board 202, a plurality of sub-word line drivers SWD arranged between the peripheral circuit board 202 and the second insulating structure 290, a plurality of interconnector structures 210 connected to the plurality of sub-word line drivers SWD, and a plurality of second bonding pad parts UP connected to the lower ends of the plurality of interconnector structures 210. The second insulating structure 290 may surround the plurality of interconnector structures 210 and the plurality of second bonding pad parts UP. The bottom surface of the second bonding pad part UP and the bottom surface of the second insulating structure 290 may be arranged on the same plane. The plurality of interconnector structures 210 may electrically connect the plurality of sub-word line drivers SWD to the plurality of second bonding pad parts UP, respectively. The peripheral circuit board 202, the second bonding pad part UP, and the second insulating structure 290 may include the same or similar material as or to the substrate 102, the first bonding pad part LP, and the first insulating structure 190, respectively. Although FIG. 4B illustrates that each of the plurality of interconnector structures 210 includes only a contact, example embodiments are not limited thereto. For example, each of the plurality of interconnector structures 210 may include at least one wiring layer and at least one contact.

The upper structure UST may be bonded to the lower structure LST by bringing the second insulating structure 290 to be in contact with the first insulating structure 190, and bringing the plurality of second bonding pad parts UP to be in contact with the plurality of first bonding pad parts LP corresponding to each other. In some example embodiments, the lower structure LST and the upper structure UST may be bonded to each other by a metal-oxide hybrid bonding method, and accordingly, the plurality of word lines WL included in the lower structure LST may be electrically connected to the plurality of sub-word line drivers SWD included in the upper structure UST. For example, the plurality of first bonding pad parts LP and the plurality of second bonding pad parts UP corresponding to each other may become the plurality of bonding pads BP that are diffusely bonded to be integrated through the diffusion of included metal atoms after being expanded and brought into contact with each other by heat. For example, the first insulating structure 190 and the second insulating structure 290 may be bonded to each other by forming a covalent bond. Among the plurality of bonding pads BP, a lower part surrounded by the first insulating structure 190 may be a first bonding pad part LP, and an upper part surrounded by the second insulating structure 290 may be a second bonding pad part UP.

One word line WL may include a pair of word line pads WLP at both ends in the first horizontal direction (X direction). A word line contact WLC may be connected to the word line pad WLP. The one word line WL may be connected to a pair of sub-word line drivers SWD, respectively through a pair of word line contacts WLC, a pair of bonding pads BP, and a pair of interconnector structures 210, respectively. The pair of word line contacts WLC, the pair of bonding pads BP, and the pair of interconnector structures 210 are connected to the pair of word line pads WLP, respectively.

The plurality of sub-word line drivers SWD may include the first sub-word line drivers SWD(A) electrically connected to first word line pads in the first step region SIR(A), and the second sub-word line drivers SWD(B) electrically connected to second word line pads in the second step region SIR(B).

The plurality of memory cells MC positioned in the stack region STR may include a first sub-memory cell group SMC(A) adjacent to the first step region SIR(A) and a second sub-memory cell group SMC(B) adjacent to the second step region SIR(B). Each of the memory cells MC included in the first sub-memory cell group SMC(A) may be electrically connected to the first sub-word line driver SWD(A) through the word line WL. Each of the memory cells MC included in the second sub-memory cell group SMC(B) may be electrically connected to the second sub-word line driver SWD(B) through the word line WL.

The semiconductor memory devices 100 according to some example embodiments include a pair of word line pads WLP at both ends of one word line WL in the first horizontal direction (X direction), and include a pair of sub-word line drivers SWD electrically connected to the pair of word line pads WLP, that is, the first sub-word line driver SWD(A) and the second sub-word line driver SWD(B), respectively, so that the number of memory cells MC arranged in the first horizontal direction (X direction) may be increased. Therefore, the degree of integration of the semiconductor memory device 100 may be increased.

FIG. 5 is a planar layout view illustrating a semiconductor memory device according to an example embodiment.

Referring to FIG. 5, a semiconductor memory device 100 includes a plurality of stack regions STR, a plurality of step regions SIR, and a plurality of isolation insulating regions ISR. A stack cell array structure CAR may be arranged in each of the stack regions STR. The plurality of stack regions STR are arranged to be spaced apart from each other in the first horizontal direction (X direction). A pair of step regions SIR may be arranged on both ends of the stack region STR in the first horizontal direction (X direction). The pair of step regions SIR arranged at both ends of the stack region STR in the first horizontal direction (X direction) may include the first step region SIR(A) arranged at one side of the stack region STR in the first horizontal direction (X direction) and the second step region SIR(B) arranged at the other side of the stack region STR in the first horizontal direction (X direction). The stack cell array structure CAR may include a first sub-memory cell group SMC(A) adjacent to the first step region SIR(A) and a second sub-memory cell group SMC(B) adjacent to the second step region SIR(B). A step structure SIS may be arranged in each of the step regions SIR(A) and SIR(B). An isolation insulating structure ISO may be arranged in each of the isolation insulating regions ISR. An isolation insulating region ISR may be arranged between a pair of step regions SIR arranged between a pair of stack regions STR adjacent to each other in the first horizontal direction (X direction), that is, between the second step region SIR(B) and the first step region SIR(A).

In the semiconductor memory devices 100 according to some example embodiments, because the pair of step regions SIR are arranged at both ends of the stack region STR in the first horizontal direction (X direction), a horizontal width of the stack region STR in the first horizontal direction (X direction) may be increased, and thus the number of isolation insulating regions ISR in which the isolation insulating structure ISO is arranged may be relatively reduced. Therefore, the degree of integration of the semiconductor memory device 100 may be increased.

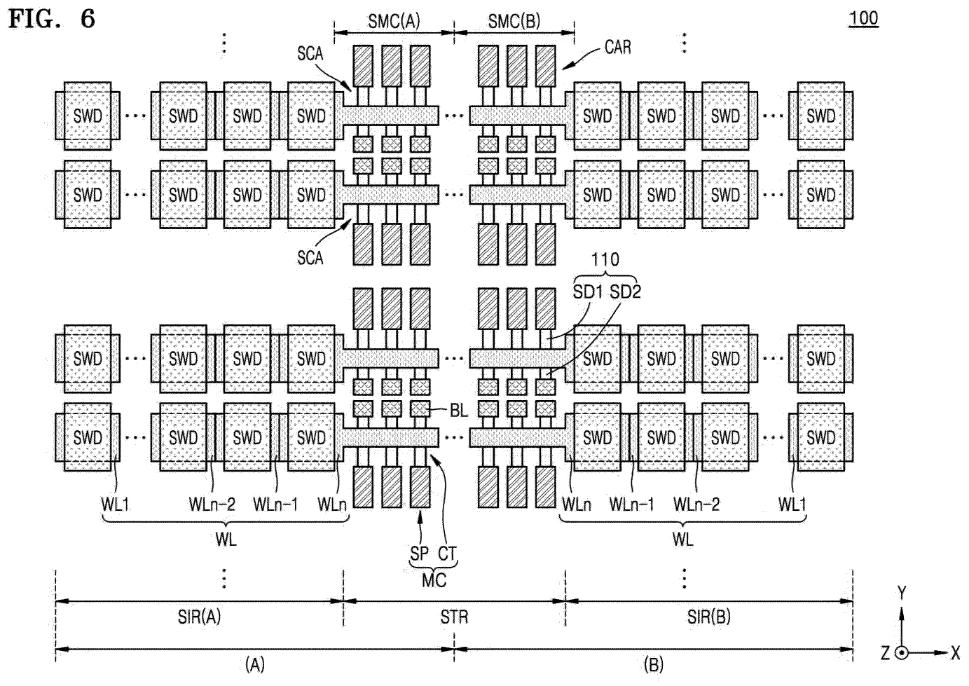

FIG. 6 is a planar layout view illustrating a semiconductor memory device according to an example embodiment.

Referring to FIG. 6, a semiconductor memory device 100 includes a stack region STR and step regions SIR. A stack cell array structure CAR may be positioned in the stack region STR, and step structures SIS may be positioned in the step regions SIR. The stack cell array structure CAR may include a plurality of sub-cell arrays SCA. The step regions SIR may be arranged on both sides of the stack region STR in the first horizontal direction (X direction). The pair of step regions SIR arranged at both ends of the stack region STR in the first horizontal direction (X direction) may include the first step region SIR(A) arranged at one side of the stack region STR in the first horizontal direction (X direction) and the second step region SIR(B) arranged at the other side of the stack region STR in the first horizontal direction (X direction). The stack cell array structure CAR may include a first sub-memory cell group SMC(A) adjacent to the first step region SIR(A) and a second sub-memory cell group SMC(B) adjacent to the second step region SIR(B).

A sub-cell array SCA may include a plurality of word lines WL, a plurality of bit lines BL, and a plurality of memory cells MC arranged between the plurality of word lines WL and the plurality of bit lines BL, each memory cell MC including a cell transistor CT and an information storage element SP.

The plurality of word lines WL extend in the first horizontal direction (X direction) and may be spaced apart from each other in the vertical direction (Z direction). The plurality of word lines WL may include a first word line WL1, . . . , an (n−2)-th word line WLn−2, an (n−1)-th word line WLn−1, and an n-th word line WLn arranged to be spaced apart from the lower side to the upper side in the vertical direction (Z direction). A pair of sub-word line drivers SWD may be connected to each of the first word line WL1, . . . , the (n−2)-th word line WLn−2, the (n−1)-th word line WLn−1, and the n-th word line WLn.

The first step region SIR(A) and the first sub-memory cell group SMC(A) may be referred to as a first sub-region A, and the second step region SIR(B) and the second sub-memory cell group SMC(B) may be referred to as a second sub-region B. The memory cells MC included in the first sub-region A may be selected by sub-word line drivers SWD connected to the word lines WL through the first step region SIR(A), and the memory cells MC included in the second sub-region B may be selected by sub-word line drivers SWD connected to the word lines WL through the second step region SIR(B). That is, the first sub-region A and the second sub-region B may operate like separate stack cell array structures.

In the semiconductor memory devices 100 according to some example embodiments, because the memory cells MC included in two or more stacked cell array structures may be configured as one stack cell array structure CAR, the degree of integration of the semiconductor memory device 100 may be increased.

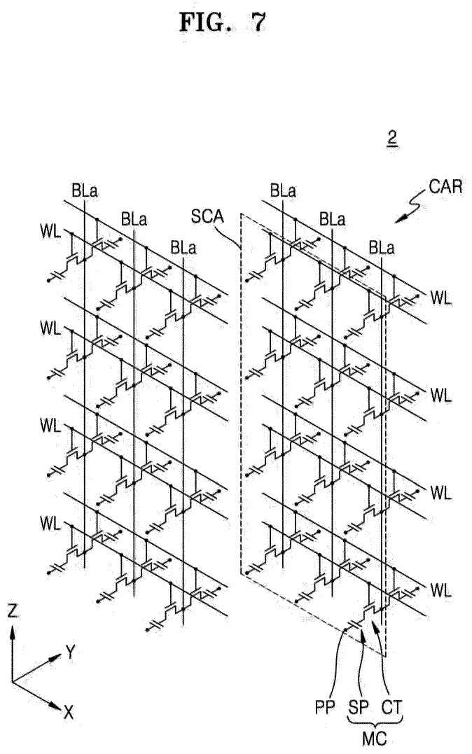

FIG. 7 is an equivalent circuit diagram illustrating a stack cell array of a semiconductor memory device according to an example embodiment.

Referring to FIG. 7, a stack cell array structure CAR of a semiconductor memory device 2 according to an example embodiment may include a plurality of sub-cell arrays SCA. Each of the sub-cell arrays SCA may include a plurality of bit lines BLa, a plurality of word lines WL, and a plurality of memory cells MC. Each of the plurality of memory cells MC includes a cell transistor CT and an information storage element SP. One cell transistor CT may be arranged between one word line WL and one bit line BLa.

The plurality of word lines WL may extend in the first horizontal direction (X direction). The word lines WL in one sub-cell array SCA may be spaced apart from each other in the vertical direction (Z direction). Bit lines BLa may extend from a substrate 102 in a vertical direction (Z direction). The bit lines BLa in one sub-cell array SCA may be spaced apart from each other in the first horizontal direction (X direction). A gate of the cell transistor CT may be connected to the word line WL, and a source region of the cell transistor CT may be connected to the bit line BLa. An information storage element SP may be connected to a drain region of the cell transistor CT.

Two sub-cell arrays SCA adjacent to each other in the second horizontal direction (Y direction) may share the bit lines BLa. Source regions of cell transistors CT included in each of the two sub-cell arrays SCA may be connected to the bit lines BLa shared by the two sub-cell arrays SCA. From the respective bit lines BLa shared by the two sub-cell arrays SCA, the source region and the drain region of the cell transistor CT and the information storage element SP of each of the two sub-cell arrays SCA may be arranged in opposite directions. For example, the source and drain regions of the cell transistor CT and the information storage element SP of one sub-cell array SCA connected to one bit line BLa shared by two sub-cell arrays SCA may be sequentially arranged in the second horizontal direction (Y direction), and the source region and the drain region of the cell transistor CT, and the information storage element SP, which are connected to the other sub-cell array SCA, may be arranged in a direction opposite to the second horizontal direction (Y direction).

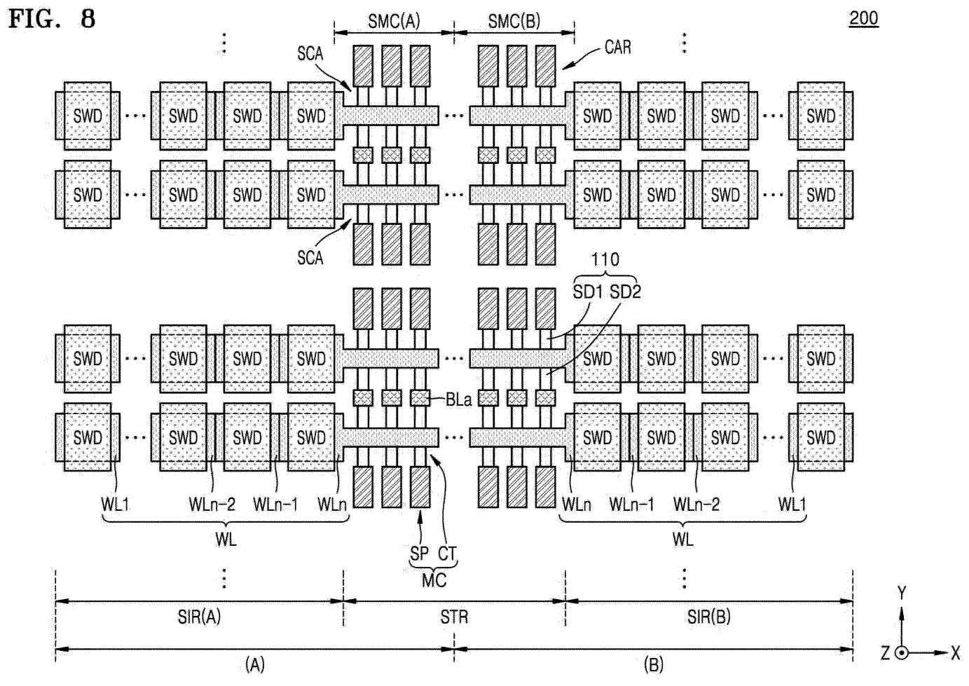

FIG. 8 is a planar layout view illustrating a semiconductor memory device according to an example embodiment.

Referring to FIG. 8, a semiconductor memory device 200 includes a stack region STR and step regions SIR. A stack cell array structure CAR may be positioned in the stack region STR, and step structures SIS may be positioned in the step regions SIR. The stack cell array structure CAR may include a plurality of sub-cell arrays SCA. The step regions SIR may be arranged on both sides of the stack region STR in the first horizontal direction (X direction). The pair of step regions SIR arranged at both ends of the stack region STR in the first horizontal direction (X direction) may include the first step region SIR(A) arranged at one side of the stack region STR in the first horizontal direction (X direction) and the second step region SIR(B) arranged at the other side of the stack region STR in the first horizontal direction (X direction). The stack cell array structure CAR may include a first sub-memory cell group SMC(A) adjacent to the first step region SIR(A) and a second sub-memory cell group SMC(B) adjacent to the second step region SIR(B).

A sub-cell array SCA may include a plurality of word lines WL, a plurality of bit lines BLa, and a plurality of memory cells MC arranged between the plurality of word lines WL and the plurality of bit lines BLa, each memory cell MC including a cell transistor CT and an information storage element SP. Two sub-cell arrays SCA adjacent to each other in the second horizontal direction (Y direction) may share the bit lines BLa. Source regions of cell transistors CT included in each of the two sub-cell arrays SCA may be connected to the bit lines BLa shared by the two sub-cell arrays SCA.

The plurality of word lines WL extend in the first horizontal direction (X direction) and may be spaced apart from each other in the vertical direction (Z direction). The plurality of word lines WL may include a first word line WL1, . . . , an (n−2)-th word line WLn−2, an (n−1)-th word line WLn−1, and an n-th word line WLn arranged to be spaced apart from the lower side to the upper side in the vertical direction (Z direction). A pair of sub-word line drivers SWD may be connected to each of the first word line WL1, . . . , the (n−2)-th word line WLn−2, the (n−1)-th word line WLn−1, and the n-th word line WLn.

The memory cells MC included in the first sub-region A may be selected by sub-word line drivers SWD connected to the word lines WL through the first step region SIR(A), and the memory cells MC included in the second sub-region B may be selected by sub-word line drivers SWD connected to the word lines WL through the second step region SIR(B).

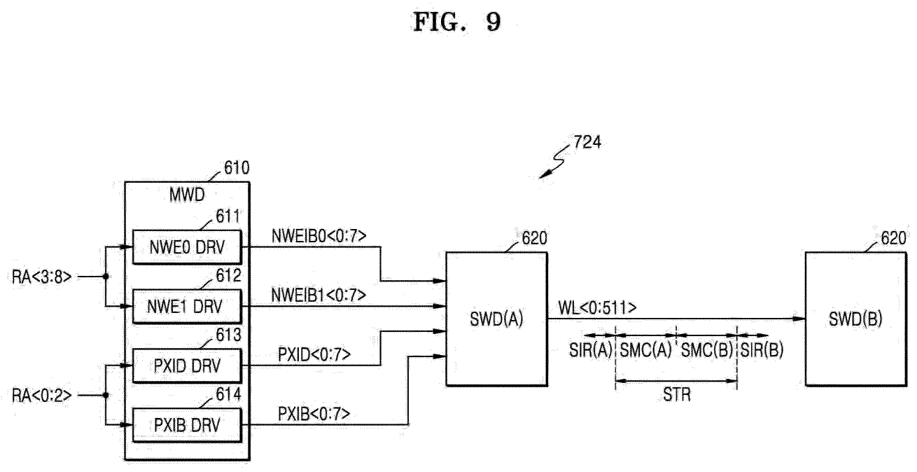

FIG. 9 is a block diagram illustrating a row decoder included in a semiconductor memory device according to an example embodiment. Specifically, FIG. 9 is a block diagram illustrating the row decoder 724 of FIG. 2.

Referring to FIG. 9, the row decoder 724 may select word lines WL corresponding to row addresses RA. As shown in FIG. 4B, the row decoder 724 may be arranged on the upper structure UST. In the present example embodiment, the row decoder 724 selects 512 word lines according to the signal configuration of the nine row addresses RA<0:8>, but example embodiments are not limited thereto, and various numbers of word lines may be selected. For example, the row decoder 724 may select 1024 or 2048 word lines WL according to the signal configuration of 10 row addresses RA<0:9> or 11 row addresses RA<0:10>.

The row decoder 724 may include a main word line driver circuit 610 and sub-word line driver circuits 620. The main word line driver circuit 610 may include first and second main word line driving signal generation circuits 611 and 612 and first and second sub-word line driving signal generation circuits 613 and 614. The main word line driver circuit 610 may generate the first and second main word line driving signals NWEIB0<0:7> and NWEIB1<0:7> based on the signals of the most significant bit (MSB) group among the row address RA<0:8>. Among the row address RA<0:8> signals, the MSB group signals may be configured as RA<3:8> row addresses. The RA<3:8> row address may be divided into an upper bit group RA<6:8> row address (hereinafter, referred to as “RA678)” and a lower bit group RA<3:5> row address (hereinafter, referred to as “RA345”).

In some example embodiments, the first main word line driving signal generation circuit 611 may generate the first main word line driving signal NWEIB0<0:7> according to decoding the RA678 row address, and the second main word line driving signal generation circuit 612 may generate the second main word line driving signal NWEIB1<0:7> according to decoding the RA345 row address. The main word line driver circuit 610 of the present embodiment divides the MSB signals RA<3:8> of the row address RA<0:8> into two groups (e.g., RA678 and RA345) and generates eight of each of first and second main word line driving signals NWEIB0<0:7> and NWEIB1<0:7> based on the two groups. In other example embodiments, the main word line driver circuit 610 may change the decoding that generates a plurality of main word line driving signals NWEIBn−1, where n is a natural number, based on a different bit number (e.g., 5, 6, and 7) of MSB group signals of row address signals according to configurations of various number of word lines (e.g., 1024 and 2048).

The second main word line driving signal generation circuit 612 may include eight second main word line driving signal generation circuits that output each of the second main word line driving signals NWEIB1<0:7> in response to the decoded RA345<0:7> row address signal. Because there are eight configurations of the decoded RA345<0:7> row address signals (e.g., 000, 001, 010, 011, 100, 101, 110 and 111), there may also be eight second main word line driving signals NWEIB1<0:7> to be activated. That is, any one of NWEIB1<0>, NWEIB1<1>, NWEIB1<2>, NWEIB1<3>, NWEIB1<4>, NWEIB1<5>, NWEIB1<6>, and NWEIB1<7> may be activated to a logic low level according to the decoded RA345<0:7> row address signal. The second main word line driving signal NWEIB1<0:7> having a logic low level may have a ground voltage VSS level and may be provided to the sub-word line driver circuit 620 connected to each of the memory blocks BLK1 to BLKi.

The main word line driver circuit 610 may generate first and second sub-word line driving signals PXID<0:7> and PXIB<0:7> based on signals of a least significant bit (LSB) group among the row address RA<0:8> signals. Among the row address RA<0:8> signals, the LSB group signals may be set to RA<0:2> row address (hereinafter, referred to as “RA012”). The main word line driver circuit 610 may include a first sub-word line driving signal generating circuit 613 for generating a first sub-word line driving signal PXID<0:7> according to decoding of the RA012 row address and a second sub-word line driving signal generating circuit 614 for generating a second sub-word line driving signal PXIB<0:3> according to decoding of the RA012 row address.

Although the main word line driver circuit 610 of the present example embodiment generates eight of each of first and second sub-word line driving signals PXID<0:3> and PXIB<0:3> based on LSB signals RA<0:2> of row address signals RA<0:8>, this is only an example to help understanding and e not intended to limit the inventive concepts.

The first sub-word line driving signal generation circuit 613 may include eight first main word line driving signal generation circuits that output each of the first sub-word line driving signals PXID<0:7> in response to the decoded RA012<0:2> row address signal. Because there are eight configurations of the decoded RA012<0:2> row address signals (e.g., 000, 001, 010, 011, 100, 101, 110 and 111), there may also be eight first sub-word line driving signals PXID<0:7> to be activated. That is, according to the decoded RA012<0:7> row address signal, any one of PXID<0>, PIXD<1>, PIXD<2>, PXID<3>, PIXD<4>, PIXD<5>, PXID<6>, and PXID<7> signals may be activated to a logic high level. The first sub-word line driving signal PXID<0:7> having a logic high level may have a high voltage VPP level and may be provided to the sub-word line driver circuit 620 connected to each of the memory blocks BLK1 to BLKi.

The second sub-word line driving signal generation circuit 614 may include eight second sub-word line driving signal generation circuits that output each of the second sub-word line driving signals PXIB<0:7> in response to the decoded RA012<0:2> row address signal. Because there are eight configurations of the decoded RA012<0:2> row address signals (e.g., 000, 001, 010, 011, 100, 101, 110 and 111), there may also be eight second sub-word line driving signals PXIB<0:7> to be activated. That is, according to the decoded RA012<0:2> row address signal, any one of PXIB<0>, PIXB<1>, PIXB<2>, PXIB<3>, PIXB<4>, PIXB<5>, PXIB<6>, and PXIB<7> signals may be activated to a logic low level. The second sub-word line driving signal PXIB<0:7> having a logic low level may have a ground voltage VSS level and may be provided to the sub-word line driver circuit 620 connected to each of the memory blocks BLK1 to BLKi.

The sub-word line driver circuit 620 may include a first sub-word line driver SWD(A) and a second sub-word line driver SWD(B). Each of the plurality of word lines WL<0:511> may be connected to a first sub-memory cell group SMC(A) and a second sub-memory cell group SMC(B) located in the stack region STR. The first sub-word line driver SWD(A) may be connected to the word line WL through the first step region SIR(A), and the second sub-word line driver SWD(B) may be connected to the word line WL through the second step region SIR(B). The word line WL selected by the first sub-word line driver SWD(A) from among the plurality of word lines WL<0:511> may select the first sub-memory cell group SMC(A), and the word line WL selected by the second sub-word line driver SWD(B) may select the second sub-memory cell group SMC(B). That is, one word line WL is connected to a pair of sub-word line drivers 620 including the first sub-word line driver SWD(A) and the second sub-word line driver SWD(B). The first sub-memory cell group SMC(A) connected to one word line WL may be selected by the first sub-word line driver SWD(A), and the second sub-memory cell group SMC(B) may be selected by the second sub-word line driver SWD(B).

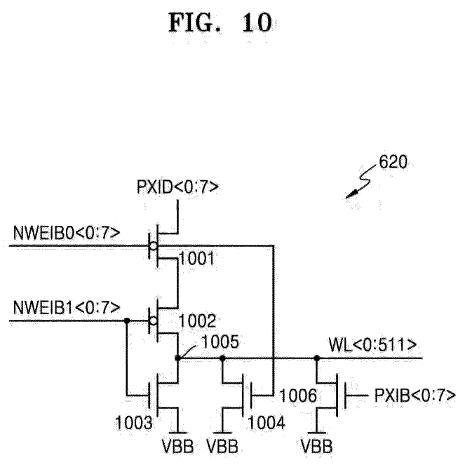

FIG. 10 is a circuit diagram illustrating a sub-word line driver circuit 620 of FIG. 9.

Referring to FIG. 10, the sub-word line driver circuit 620 may include first to fifth transistors 1001, 1002, 1003, 1004, and 1006. The first and second transistors 1001 and 1002 may be connected in series between the first sub-word line driving signal PXID<0:7> and the connection nodes 1005 of the second to fourth transistors 1002 to 1004. The gate of the first transistor 1001 is connected with the first main word line driving signal NWEIB0<0:7>, and the gate of the second transistor 1002 is connected with the second main word line driving signal NWEIB1<0:7>. The third and fourth transistors 1003 and 1004 are connected in parallel between the connection node 1005 of the second to fourth transistors 1002 to 1004 and the negative voltage VBB line. The gate of the third transistor 1003 is connected with the second main word line driving signal NWEIB1<0:7>, and the gate of the fourth transistor 1004 is connected with the first main word line driving signal NWEIB0<0:7>. The fifth transistor 1006 may be configured as an NMOS transistor in which a negative voltage VBB line is connected to a source thereof, a connection node 1005 of the second to fourth transistors 1002 to 1004 is connected to the drain thereof, and a second sub-word line driving signal PXIB<0:7> is applied to the gate thereof. The connection node 1005 of the second to fourth transistors 1002 to 1004 may be connected to the plurality of word lines WL<0:511> of the memory blocks BLK1 to BLKi. The first to fourth transistors 1001 to 1004 of the sub-word line driver circuit 620 may be implemented as a NOR logic circuit.

The sub-word line driver circuit 620 may include 512 sub-word line driver circuits respectively connected to the plurality of word lines WL<0:511> in response to the first main word line driving signal NWEIB0<0:7>, the second main word line driving signal NWEIB1<0:7>, the first sub-word line driving signal PXID<0:7>, and the second sub-word line driving signal PXIB<0:7>. The sub-word line driver circuit 620 may select one of the plurality of word lines WL<0:511> to be activated into a logic high level, in response to a logic low level of the first main word line driving signal NWEIB0<0:7> to be activated, a logic low level of the second main word line driving signal NWEIB1<0:7> to be activated, a logic high level of the first sub-word line driving signal PXID<0:7> to be activated, and a logic low level of the second sub-word line driving signal PXIB<0:7> to be activated. A word line selected from among the plurality of word lines WL<0:511> may be activated to a high voltage level of the first sub-word line driving signal PXID<0:7> having a logic high level.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While the inventive concepts has been particularly shown and described with reference to some example embodiments thereof, it will be understood that various changes in form and details may be made therein without departing from the spirit and scope of the following claims.

What is claimed is:

1. A semiconductor memory device comprising:
a substrate including a stack region, the stack region including a first step region and a second step region, the first step region and the second step region being at both ends of the stack region, respectively, in a first horizontal direction;
a plurality of word lines each extending in the first horizontal direction in the stack region toward each of the first step region and the second step region, the plurality of word lines being spaced apart from each other in a vertical direction;
a plurality of bit lines extending in the vertical direction in the stack region, the plurality of bit lines spaced apart from each other in the first horizontal direction;
a plurality of memory cells between the plurality of word lines and the plurality of bit lines in the stack region;
a first word line contact connected to each of the plurality of word lines in the first step region;
a second word line contact connected to each of the plurality of word lines in the second step region; and
a first sub-word line driver and a second sub-word line driver connected to the first word line contact and the second word line contact, respectively.

2. The semiconductor memory device of claim 1, wherein each of the plurality of word lines is electrically connected to the first sub-word line driver through the first word line contact, and is electrically connected to the second sub-word line driver through the second word line contact.

3. The semiconductor memory device of claim 1, wherein each of the plurality of memory cells includes a cell transistor and an information storage element, wherein the cell transistor comprises a semiconductor pattern extending from each of the plurality of bit lines in a second horizontal direction different from the first horizontal direction.

4. The semiconductor memory device of claim 3, wherein the semiconductor pattern includes:
a source region connected to each of the plurality of bit lines;
a channel region; and
a drain region connected to the information storage element,
wherein the source region, the channel region, and the drain region are sequentially arranged from each of the plurality of bit lines in the second horizontal direction.

5. The semiconductor memory device of claim 4, wherein the information storage element comprises a capacitor, the capacitor comprising a first electrode connected to the drain region, a capacitor dielectric layer covering the first electrode, and a second electrode covering the capacitor dielectric layer.

6. The semiconductor memory device of claim 4, wherein
the semiconductor pattern passes through each of the plurality of word lines, and
the channel region is a part of the semiconductor pattern that passes through each of the plurality of word lines.

7. The semiconductor memory device of claim 1, wherein, among the plurality of memory cells, memory cells adjacent to the first step region are configured to be selected by the first sub-word line driver, and other memory cells adjacent to the second step region are configured to be selected by the second sub-word line driver.

8. The semiconductor memory device of claim 1, wherein each of the plurality of word lines extends in the first horizontal direction through the stack region from the first step region to the second step region.

9. The semiconductor memory device of claim 8, wherein an extension length of the plurality of word lines in the first horizontal direction decreases from bottom to top in the vertical direction, so that the plurality of word lines have a step structure in each of the first step region and the second step region.

10. The semiconductor memory device of claim 9, wherein
each of the plurality of word lines comprises a first word line pad and a second word line pad at both ends thereof in the first horizontal direction, respectively,
no other word lines among the plurality of word lines are at an upper side of the first word line pad and the second word line pad in the vertical direction, and
the first word line contact and the second word line contact are connected to the first word line pad and the second word line pad, respectively.

11. A semiconductor memory device comprising:
a lower structure; and
an upper structure stacked on the lower structure, the upper structure including a first sub-word line driver and a second sub-word line driver,
wherein the lower structure comprises
a substrate including a stack region, the stack region including a first step region and a second step region, the first step region and the second step region being at both ends of the stack region, respectively, in a first horizontal direction,
a plurality of word lines each extending in the first horizontal direction in the stack region toward each of the first step region and the second step region, the plurality of word lines being spaced apart from each other in a vertical direction,
a plurality of bit lines extending in the vertical direction in the stack region, the plurality of bit lines spaced apart from each other in the first horizontal direction,
a plurality of memory cells between the plurality of word lines and the plurality of bit lines in the stack region,
a first word line contact connected to each of the plurality of word lines in the first step region, and
a second word line contact connected to each of the plurality of word lines in the second step region,
wherein each of the plurality of word lines is electrically connected to the first sub-word line driver through the first word line contact, and is electrically connected to the second sub-word line driver through the second word line contact.

12. The semiconductor memory device of claim 11, wherein
the lower structure comprises a first insulating structure covering the plurality of word lines, the plurality of bit lines, the plurality of memory cells, the first word line contact, and the second word line contact on the substrate, and
the upper structure comprises a peripheral circuit board, an interconnector structure and a second insulating structure, the interconnector structure connecting the first sub-word line driver and the second sub-word line driver with the first word line contact and the second word line contact, respectively, and the second insulating structure surrounding and covering the interconnector structure under the peripheral circuit board and being in contact with the first insulating structure.

13. The semiconductor memory device of claim 12, further comprising:
a bonding pad connecting each of the first word line contact and the second word line contact with the interconnector structure, wherein
a lower part of the bonding pad is surrounded by the first insulating structure, and an upper part of the bonding pad is surrounded by the second insulating structure.

14. The semiconductor memory device of claim 11, wherein
each of the plurality of memory cells includes a cell transistor and an information storage element,
the cell transistor comprises a semiconductor pattern including a source region, a channel region, and a drain region, and
the source region, the channel region, and the drain region are sequentially arranged from each of the plurality of bit lines in a second horizontal direction different from the first horizontal direction.

15. The semiconductor memory device of claim 14, wherein the source region is connected to each of the plurality of bit lines, the drain region is connected to the information storage element, and the channel region is surrounded by each of the plurality of word lines.

16. The semiconductor memory device of claim 11, wherein the first sub-word line driver is configured to select memory cells adjacent to the first step region from among the plurality of memory cells, and the second sub-word line driver is configured to select other memory cells adjacent to the second step region from among the plurality of memory cells.

17. The semiconductor memory device of claim 11, wherein
each of the plurality of word lines extends in the first horizontal direction through the stack region from the first step region to the second step region,
an extension length of each of the plurality of word lines in the first horizontal direction decreases from bottom to top in the vertical direction,
the plurality of word lines have a step structure having a first word line pad and a second word line pad,
the first word line contact is connected to the first word line pad in the first step region, and
the second word line contact is connected to the second word line pad in the second step region.

18. A semiconductor memory device comprising:
a lower structure; and
an upper structure stacked on the lower structure, the upper structure including a first sub-word line driver and a second sub-word line driver,
wherein the lower structure comprises
a substrate including a stack region, the stack region including a first step region and a second step region, the first step region and the second step region being at both ends of the stack region, respectively, in a first horizontal direction,
a plurality of word lines each extending in the first horizontal direction in the stack region toward each of the first step region and the second step region, the plurality of word lines being spaced apart from each other in a vertical direction,
a plurality of bit lines extending in the vertical direction in the stack region, the plurality of bit lines spaced apart from each other in the first horizontal direction,
a plurality of memory cells between the plurality of word lines and the plurality of bit lines in the stack region,
a first word line contact connected to each of the plurality of word lines in the first step region, and
a second word line contact connected to each of the plurality of word lines in the second step region,
each of the plurality of word lines is electrically connected to the first sub-word line driver through the first word line contact, and is electrically connected to the second sub-word line driver through the second word line contact,
each of the plurality of memory cells includes a cell transistor and an information storage element, the cell transistor includes a semiconductor pattern including a source region connected to a corresponding one of the plurality of bit lines, a channel region surrounded by a corresponding one of the plurality of word lines, and a drain region connected to the information storage element, and
the source region, the channel region, and the drain region are sequentially arranged from the corresponding one of the plurality of bit lines in a second horizontal direction different from the first horizontal direction.

19. The semiconductor memory device of claim 18, further comprising:
a bonding pad connected to each of the first word line contact and the second word line contact, wherein
the lower structure comprises a first insulating structure covering the plurality of word lines, the plurality of bit lines, the plurality of memory cells, the first word line contact, and the second word line contact on the substrate,
the upper structure comprises a peripheral circuit board, an interconnector structure connecting each of the first sub-word line driver and the second sub-word line driver to the bonding pad, and a second insulating structure surrounding and covering the interconnector structure and contacting the first insulating structure under the peripheral circuit board, and
a lower part of the bonding pad is surrounded by the first insulating structure, and an upper part of the bonding pad is surrounded by the second insulating structure.

20. The semiconductor memory device of claim 18, wherein
the first sub-word line driver is connected to each of the plurality of word lines through the first word line contact and is configured to select memory cells adjacent to the first step region from among the plurality of memory cells, and
the second sub-word line driver is connected to each of the plurality of word lines through the second word line contact and is configured to select other memory cells adjacent to the second step region from among the plurality of memory cells.
